(19) United States
(12) Patent Application Publication
(10) Pub. No.: US 2018/0182739 A1
(43) Pub. Date: Jun. 28, 2018

(54) LIGHT-EMITTING DIODE ARRANGEMENT AND METHOD FOR THE PRODUCTION THEREOF

(71) Applicant: OSRAM Opto Semiconductors GmbH, Regensburg (DE)

(72) Inventor: Farhang GHASEMI AFSHAR, Wenzenbach (DE)

(21) Appl. No.: 15/736,790

(22) PCT Filed: Jun. 3, 2016
(86) PCT No.: PCT/EP2016/062626

§ 371 Date: Dec. 15, 2017

(30) Foreign Application Priority Data
Jun. 17, 2015 (DE) 10 2015 007 750.3

(51) Int. Cl. H01L 25/075; H01L 33/54; H01L 33/50; H01L 33/58; H01L 33/60; H01L 33/62

(52) U.S. Cl. CPC H01L 25/0753; H01L 33/54; H01L 33/507; H01L 33/58; H01L 33/60; H01L 33/642; H01L 2933/0066; H01L 2933/005; H01L 2933/0041; H01L 2933/0058; H01L 33/62

(57) ABSTRACT

According to the present disclosure, a light-emitting diode arrangement provides a substrate, first LEDs, which are arranged on the substrate, second LEDs, which are arranged on the substrate laterally adjacent to the first LEDs, at least one cover body, which covers the first LEDs, at least one dam, which is arranged on the substrate and which encloses the first LEDs and the second LEDs in the lateral direction, and a first potting material, which covers the second LEDs and is delimited in the lateral direction by the dam and the cover body. The cover body and/or the first potting material include(s) a first converter material for converting electromagnetic radiation.

### RELATED APPLICATIONS

The present application is a national stage entry according to 35 U.S.C. § 371 of PCT application No.: PCT/EP2016/062626 filed on Jun. 3, 2016, which claims priority from German application No. 10 2015 007 750.3 filed on Jun. 17, 2015, and is incorporated herein by reference in its entirety.

### TECHNICAL FIELD

The present disclosure relates to a light-emitting diode arrangement and a method for producing a light-emitting diode arrangement.

### BACKGROUND

In a conventional light-emitting diode arrangement, multiple LEDs are arranged on a substrate and electrically connected to electrical lines, which are formed on the substrate. The LEDs can be electrically connected in parallel and/or electrically connected in series. For example, the LEDs of one group of LEDs can be electrically connected in series, the LEDs of another group of LEDs can be electrically connected in series, and the two groups can be electrically connected in parallel. The LEDs can be designed as structurally equivalent or different. For example, one group of LEDs may include surface-emitting light-emitting diodes, which typically include an electrical contact on the upper side thereof and an electrical contact on the lower side thereof, and another group of LEDs may include volume-emitting light-emitting diodes, which typically include both electrical contacts on the upper side thereof. Furthermore, one group of LEDs may include blue-light-emitting light-emitting diodes and another group of LEDs may include red-light-emitting light-emitting diodes. The LEDs can be formed on a substrate, for example, which has a ceramic base body, on which the electrical lines for electrically contacting the LEDs are formed.

### SUMMARY

One object of the present disclosure is to provide a light-emitting diode arrangement, which is producible simply and/or cost-effectively, which is particularly efficient, which has a particularly long service life, and/or which is particularly compact.

One object of the present disclosure is to provide a method for producing a light-emitting diode arrangement, which can be carried out simply and/or cost-effectively and/or which contributes to the light-emitting diode arrangement being particularly efficient, having a particularly long service life, and/or being particularly compact.

One object is achieved according to one aspect of the present disclosure by a light-emitting diode arrangement, including a substrate; first LEDs, which are arranged on the substrate; second LEDs, which are arranged on the substrate laterally adjacent to the first LEDs; at least one cover body, which covers the first LEDs; at least one dam, which is arranged on the substrate and which encloses the first LEDs and the second LEDs in the lateral direction; and a first potting material, which covers the second LEDs and which is delimited in the lateral direction by the dam and the cover body, wherein the cover body and/or the first potting material include(s) a first converter material for converting electromagnetic radiation.

The cover body, which is arranged above, in particular on, the first LEDs, protects the first LEDs from external force effects, for example, from impacts and/or scratches, and can be used during the production of the light-emitting diode arrangement to prevent the first potting material from flowing over the first LEDs. The cover body and the dam therefore form lateral delimitations of a cavity, into which the first potting material is decanted during the production of the light-emitting diode arrangement and in which the first potting material is subsequently arranged. The cover body therefore has the double function that it protects the first LEDs, on the one hand, and is used as the lateral delimitations for the first potting material, on the other hand. One, two, three, or more cover bodies can be arranged, which each cover and protect a plurality of the first LEDs. The cover body or bodies may include, for example, a plastic and/or silicone or can be formed thereof. The light-emitting diode arrangement is color adjustable and/or CCT tunable.

The electromagnetic radiation is emitted by the first LEDs and/or the second LEDs. At least a part of the electromagnetic radiation is converted by means of the converter material. In particular, the converter material absorbs a part of the electromagnetic radiation, which has a specific wavelength or is in a specific wavelength range, and emits electromagnetic radiation, which has another wavelength or is in another wavelength range. The electromagnetic radiation can be, for example, light in the visible wavelength range. For example, the electromagnetic radiation can be red, green, or blue light. The converted electromagnetic radiation can be red or white light, for example.

A vertical height of the cover body and/or a vertical height of the dam can each be greater measured from a surface of the substrate than a thickness of the layer which is formed by the first potting material. The first LEDs can be arranged along a line, for example. In addition, two or more such lines of first LEDs can be arranged in parallel to one another or along intersecting lines. The first LEDs within one of these lines can be electrically connected in series, for example. The second LEDs can be arranged along a line, for example. In addition, two or more such lines of second LEDs can be arranged in parallel to one another or along intersecting lines. The second LEDs within one of these lines can be electrically connected in series, for example. The lines of LEDs can be electrically connected in parallel or electrically connected in series.

In one refinement, the cover body is formed as a beamforming element for influencing a beam path of electromagnetic radiation emitted by the first LEDs, in particular as an optical lens. In other words, the cover body is used not only as a protection for the first LEDs and as a delimitation for the first potting material, but rather also for beamforming of one or more beam paths of the electromagnetic radiation which is emitted by the first LEDs. In addition, by means of the cover body as a beamforming element, an efficiency of the light-emitting diode arrangement, in particular of the first LEDs, can be increased, since a component of the electromagnetic radiation generated by the first LEDs, which leaves the light-emitting diode arrangement as usable light, can be increased in relation to a light-emitting diode arrangement without corresponding beamforming element. In particular, the beamforming element can be used for the purpose of reducing an internal total reflection of the electromagnetic radiation generated by the first LEDs, so that a particularly large component of the electromagnetic radiation can leave the light-emitting diode arrangement. This is particularly advantageous if the first LEDs emit red light, since the critical angle for the total reflection is particularly small in the case of red light.

The cover body therefore has the four functions of the protection of the first LEDs, the delimitation of the first potting material, the beamforming of the electromagnetic radiation emitted by the first LEDs, and the increase of the efficiency of the light-emitting diode arrangement. In addition to the advantages inherent to these functions, this has the additional advantage that a particularly small amount of space is required on the substrate, since individual bodies do not have to be arranged for the individual functions, but rather all of these functions are assumed by the cover body or bodies.

In one refinement, the cover body is made transparent and the first potting material includes the first converter material. The electromagnetic radiation, which is generated by the first LEDs, therefore exits from the cover body without wavelength conversion. The electromagnetic radiation generated by the second LEDs, in contrast thereto, is at least partially converted with respect to its wavelength spectrum. For example, a part of the electromagnetic radiation generated by the second LEDs can be converted and can mix with the nonconverted part of the electromagnetic radiation generated by the second LEDs. A mixed light is thus generated having a wavelength spectrum, which is composed of the wavelength spectrum of the electromagnetic radiation generated by the second LEDs and the wavelength spectrum of the converted electromagnetic radiation. The electromagnetic radiation generated by the second LEDs and/or the converted electromagnetic radiation can mix with the electromagnetic radiation emitted by the first LEDs. Electromagnetic radiation can thus in turn be generated having a wavelength spectrum composed of the individual wavelength spectra. For example, the electromagnetic radiation can be generated and the wavelength spectra can be mixed such that the light-emitting diode arrangement emits white light.

Alternatively to only the first potting material including converter material, only the cover body may include converter material and the first potting material can be transparent. Alternatively thereto, the cover body and the first potting material may include converter material. In the latter case, the cover body and the first potting material may include the same or different converter materials.

In one refinement, the first LEDs emit electromagnetic radiation in the wavelength range of red visible light, in particular red light, and the second LEDs emit electromagnetic radiation in the wavelength range of blue visible light, in particular blue light. This can contribute to generating white light by means of the light-emitting diode arrangement, wherein the blue light can be completely or partially converted for this purpose, for example, into mint-colored or yellow light.

In one refinement, the first LEDs are surface-emitting light-emitting diodes and the second LEDs are volume-emitting light-emitting diodes. For example, the first LEDs can be surface-emitting light-emitting diodes which generate red light and the second LEDs can be volume-emitting light-emitting diodes which generate blue light. This can contribute to the first LEDs, in particular the light-emitting diodes which emit red light, being easily producible.

In one refinement, the substrate includes a ceramic body, which has a highly reflective surface, on which the first LEDs and the second LEDs are arranged, and electrical lines, which are formed on the ceramic body and which are electrically coupled to the first LEDs and the second LEDs. This enables the highly reflective surface of the ceramic body to be able to be used as a receptacle surface for the first LEDs and the second LEDs.

In one refinement, the substrate includes a metal core board, on which the first LEDs are arranged, and a metal template, which is arranged on the metal core board, the surface of which facing away from the metal core board is highly reflective, and on which the second LEDs are arranged and which includes recesses, in which the first LEDs are arranged and through which the cover bodies protrude. This enables the first LEDs to be arranged on the metal core board, whereby a particularly good heat dissipation away from the first LEDs is possible, and the second LEDs to be arranged on the highly reflective surface of the metal template, whereby light decoupling from the second LEDs is particularly good. This is advantageous in particular if the first LEDs are red-light-emitting light-emitting diodes, since they are typically particularly temperature sensitive such that the efficiency thereof decreases strongly with increasing temperature, and since the efficiency of the first LEDs and therefore of the light-emitting diode arrangement can be particularly high due to the good thermal coupling via the metal core board. In addition, this is advantageous in particular if the second LEDs are volume-emitting light-emitting diodes, since the light decoupling thereof in conjunction with the highly reflective surface of the metal template is particularly good. Moreover, the first LEDs, if they are surface-emitting light-emitting diodes, can be arranged directly on the metal core board and electrically connected thereto, for example, by soldering.

A thickness of the metal template is less, for example, significantly less, than a vertical height of the cover bodies. The fact that the surface of the metal template and/or the ceramic body is highly reflective can mean, for example, that a reflectivity of the highly reflective surface is in a range, for example, of 90% to 98%, for example, 92% to 96%, for example, 94% to 95%.

In one refinement, the light-emitting diode arrangement includes third LEDs, which are arranged on the substrate laterally adjacent to the first LEDs and the second LEDs. The third LEDs can be used to generate light having a wavelength spectrum which does not correspond to the wavelength spectrum of the electromagnetic radiation generated by the first LEDs or the wavelength spectrum of the electromagnetic radiation generated by means of the second LEDs. Alternatively or additionally, the electromagnetic radiation of the third LEDs can be converted by means of a second converter material such that the wavelength spectrum of the converted electromagnetic radiation does not correspond to the wavelength spectrum of the electromagnetic radiation generated by the first LEDs or the wavelength spectrum of the electromagnetic radiation generated by the second LEDs or the wavelength spectrum of the electromagnetic radiation generated by the first converter material.

In one refinement, the third LEDs are designed as structurally equivalent to the first LEDs or the second LEDs.

In one refinement, a second potting material, which includes a second converter material for converting electromagnetic radiation, covers the third LEDs. For example, the second LEDs and the third LEDs can be designed as structurally equivalent and the first LEDs can be covered by the first potting material having the first converter material and the second LEDs can be covered by the second potting material having the second converter material. This enables light having different wavelength spectra to be generated by the second LEDs and the third LEDs, although they are structurally equivalent.

In one refinement, the light-emitting diode arrangement includes at least one intermediate dam, which is arranged on the substrate laterally between the first LEDs, the second LEDs, and/or the third LEDs and which delimits the first potting material and/or the second potting material in the lateral direction. The intermediate dam can be understood by way of illustration as a dummy cover body, which does not cover any LEDs and therefore is not used as a beamforming element, nor has a protective function, but otherwise acts like the cover body. In particular, the intermediate dam is used as a delimitation for the first potting material and/or the second potting material. Moreover, the intermediate dam can optionally correspond to the cover body with respect to its shape. A vertical height of the intermediate dam measured from the substrate can be greater than a height of the first potting material and/or the second potting material.

One object is achieved according to one aspect of the present disclosure by a method for producing a light-emitting diode arrangement. In the method, the substrate is provided; the first LEDs are arranged on the substrate; the second LEDs are arranged on the substrate laterally adjacent to the first LEDs; at least the one cover body is formed and arranged over the first LEDs so that it covers the first LEDs; at least the one dam is arranged on the substrate so that it encloses the first LEDs and the second LEDs in the lateral direction; the first potting material is poured in the liquid state between the cover body and the dam over the second LEDs so that it is delimited in the lateral direction by the dam and the cover body, wherein the cover body and/or the first potting material includes the first converter material for converting electromagnetic radiation; and the first potting material is dried and/or cured.

The cover body and the dam form the lateral delimitation for the first potting material and a cavity into which the first potting material can be decanted. The cover body and the dam cause the first potting material to remain in the liquid state at the intended location for the first potting material, in particular over the second LEDs, and not to flow unobstructed over the substrate.

In one refinement, the cover body is formed as a beamforming element for influencing the beam path of the electromagnetic radiation emitted by the first LEDs, in particular as an optical lens.

In one refinement, the first LEDs are arranged on the metal core board. The cover body is arranged over the first LEDs. The metal template, the surface of which facing away from the metal core board is highly reflective and which includes the recesses, is formed and arranged on the metal core board so that the first LEDs are arranged in the recesses and the cover body protrudes through the recesses. The second LEDs are arranged on the highly reflective surface of the metal template. The metal core board and the metal template form the substrate.

In one refinement, the third LEDs are arranged on the substrate laterally adjacent to the first LEDs and the second LEDs. The second potting material, which includes a second converter material for converting electromagnetic radiation, is poured in the liquid state over the third LEDs such that it covers the third LEDs. The second potting material is dried and/or cured.

In one refinement, the intermediate dam is formed on the substrate laterally between the first LEDs, the second LEDs, and/or the third LEDs so that it delimits the first potting material and/or the second potting material in the lateral direction.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the disclosed embodiments. In the following description, various embodiments described with reference to the following drawings, in which:

FIG. 1 shows a perspective view of an embodiment of a light-emitting diode arrangement;

FIG. 2 shows a perspective sectional illustration through the light-emitting diode arrangement according to FIG. 1;

FIG. 3 shows a perspective view of a state of the light-emitting diode arrangement according to FIG. 1 during its production;

FIG. 4 shows a perspective sectional illustration through the light-emitting diode arrangement according to FIG. 3;

FIG. 5 shows a perspective illustration of a metal template;

FIG. 6 shows a perspective view of a state of the light-emitting diode arrangement according to FIG. 1 during its production;

FIG. 7 shows a perspective sectional illustration through the light-emitting diode arrangement according to FIG. 6;

FIG. 8 shows a perspective view of a state of the light-emitting diode arrangement according to FIG. 1 during its production;

FIG. 9 shows a perspective sectional illustration through the light-emitting diode arrangement according to FIG. 8;

FIG. 10 shows a perspective view of a state of the light-emitting diode arrangement according to FIG. 1 during its production;

FIG. 11 shows a perspective sectional illustration through the light-emitting diode arrangement according to FIG. 10;

FIG. 12 shows a sectional illustration of a state of the light-emitting diode arrangement according to FIG. 1 during its production;

FIG. 13 shows a sectional illustration of a state of an embodiment of a light-emitting diode arrangement during its production;

FIG. 14 shows a perspective view of an embodiment of a light-emitting diode arrangement.

### DETAILED DESCRIPTION

In the following comprehensive description, reference is made to the appended drawings, which form part of this description and in which specific exemplary embodiments are shown for illustration, in which the present disclosure can be performed. Since components of embodiments can be positioned in a number of various orientations, the directional terminology is used for illustration and is in no way restrictive. It is apparent that other embodiments can be used and structural or logical modifications can be performed without deviating from the scope of protection of the present disclosure. It is apparent that the features of the various embodiments described herein can be combined with one another, if not specifically indicated otherwise. The following comprehensive description is therefore not to be understood in a restrictive sense, and the scope of protection of the present disclosure is defined by the appended claims. In the figures, identical or similar elements are provided with identical reference signs, if this is expedient.

A light-emitting diode arrangement may include two, three, or more light-emitting diodes (LEDs). A light-emitting diode arrangement can optionally also include one, two, or more electronic components. An electronic component may include, for example, an active and/or a passive component. An active electronic component may include, for example, a computer, control, and/or regulating unit and/or a transistor. A passive electronic component may include, for example, a capacitor, a resistor, a diode, or a coil.

An LED is a component which emits electromagnetic radiation. The electromagnetic radiation can be, for example, light in the visible range, UV light, and/or infrared light.

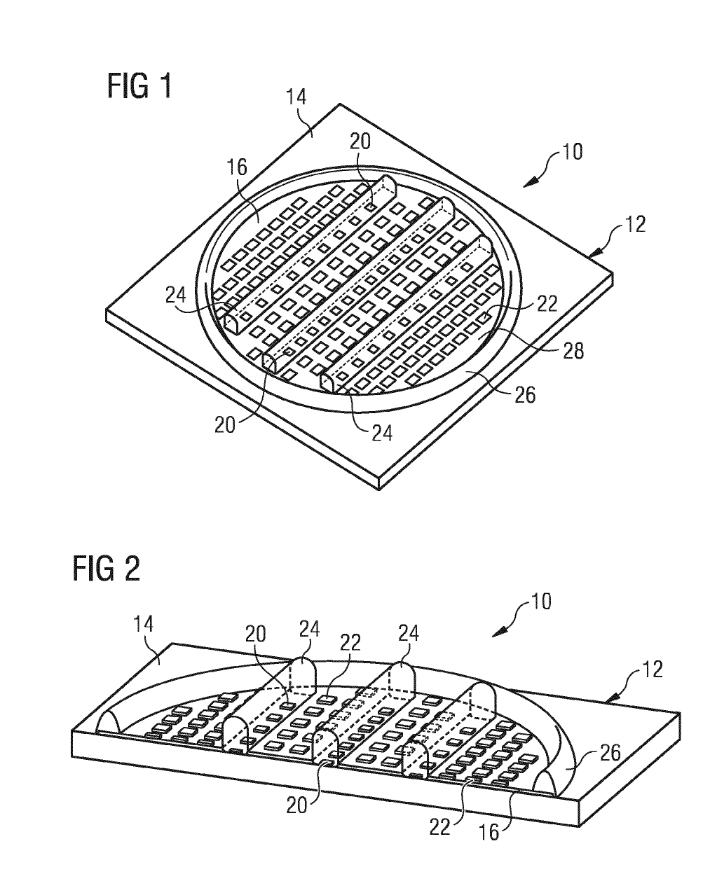

FIG. 1 shows a perspective view of an embodiment of a light-emitting diode arrangement 10. The light-emitting diode arrangement 10 includes a substrate 12. The substrate 12 includes a main body, in particular a metal core board 14, and a layer on the main body, which is formed in particular by a metal template 16. First LEDs 20 are arranged on the substrate 12. Second LEDs 22 are arranged on the substrate 12 laterally adjacent to the first LEDs 20. Cover bodies 24, which cover and protect the first LEDs 20, are arranged above the first LEDs 20. A first potting material 28, which covers the second LEDs 22, is formed over the second LEDs 22. A dam 26 is arranged on the substrate 12 and extends around the first LEDs 20, the second LEDs 22, and the cover body 24 and encloses the first LEDs 20, the second LEDs 22, and the cover body 24 in the lateral direction. The first potting material 28 is delimited in the lateral direction by the cover bodies 24 and the dam 26. The first potting material 28 is transparent in FIG. 1 and is therefore illustrated as nonvisible and the first potting material 28 is illustrated in FIG. 12 and explained in greater detail in particular with reference to FIG. 12.

The first LEDs 20 are arranged on the metal core board 14, in particular directly on the metal core board 14. The first LEDs 20 are arranged along three straight lines, wherein the straight lines are parallel to one another. Alternatively thereto, the first LEDs 20 can be arranged along more or less straight lines and/or the first LEDs 20 can be arranged along non-straight lines, for example, curved, circular, or angled lines.

The first LEDs 20 are surface-emitting light-emitting diodes. The first LEDs 20 are red-light-emitting light-emitting diodes. Moreover, the first LEDs 20 include thin-film chips. Alternatively thereto, the first LEDs 20 can be volume-emitting light-emitting diodes and/or light-emitting diodes which emit light other than red light, for example, blue light, and/or may include sapphire chips.

The second LEDs 22 are arranged on the metal template 16, in particular directly on the metal template 16. The second LEDs 22 are arranged along straight lines, wherein the straight lines are parallel to one another. Alternatively thereto, the second LEDs 22 can be arranged along more or less straight lines and/or the second LEDs 22 can be arranged along non-straight lines, for example, curved, circular, or angled lines.

The second LEDs 22 are volume-emitting light-emitting diodes. The second LEDs 22 are blue-light-emitting light-emitting diodes. Moreover, the second LEDs 22 include sapphire chips. Alternatively thereto, the second LEDs 22 can be surface-emitting light-emitting diodes and/or light-emitting diodes which emit a light other than blue light, for example, red light, and/or may include thin-film chips.

The metal core board 14 includes a metal core, for example, made of aluminum or copper, a dielectric layer applied to the metal core, and an electrically conductive layer, for example, made of copper, applied to the dielectric layer. Because of the metal core, the metal core board 14 has particularly good thermal conductivity. The electrically conductive layer is used for electrically contacting the first LEDs 20, wherein a plurality of electrical lines (not shown) can be formed by the electrically conductive layer.

The metal template 16 may include a carrier, for example, which is coated using a highly reflective layer. Optionally, the highly reflective layer can be coated using a transparent protective layer.

For example, the metal template 16 includes an aluminum carrier, which is coated using a highly reflective silver layer, which is coated for protection using a transparent dielectric material. Furthermore, the metal template 16 may include multiple conductor tracks (not shown), which can be formed on the transparent dielectric material, for example, and which can be used for electrically contacting the second LEDs 22.

The cover bodies 24 are arranged directly on the first LEDs 20 and directly on the substrate 12, in particular directly on the metal core board 14. The cover bodies 24 have a greater height, at least measured from a surface of the substrate 12 adjoining the first potting material 28, than the first potting material 28. The cover bodies 24 have the shape of an optical lens for beamforming a beam path of the electromagnetic radiation generated by the first LEDs 20 on the side thereof facing away from the first LEDs 20. The cover bodies 24 are therefore designed as beamforming elements. Alternatively thereto, the cover bodies 24 cannot have the shape of an optical lens for beamforming a beam path of the electromagnetic radiation generated by the first LEDs 20 on the side thereof facing away from the first LEDs 20, but rather can be formed as planar or flat, for example. The cover bodies 24 are made transparent or at least translucent. That is to say, the cover bodies are at least essentially transparent or include scattering elements for scattering the electromagnetic radiation generated by the first LEDs 20. The cover bodies 24 may include silicone, for example, HRI (high-refractive index) silicone, or glass, or can be formed thereof.

The dam 26 includes a plastic or is formed thereof. For example, the dam 26 includes silicone or is formed thereof. Moreover, the dam 26 may include a highly reflective material, for example, titanium dioxide. The highly reflective material can be embedded, for example, in the dam 26. The dam 26 has a height, at least measured from a surface of the substrate 12 adjoining the first potting material 28, which is greater than a height of the first potting material 28.

Optionally, the light-emitting diode arrangement 10 may include a driver circuit for operating the LEDs 20, 22. Alternatively thereto, the light-emitting diode arrangement 10 can be electrically connected to the driver circuit for operating the LEDs 20, 22.

FIG. 2 shows a perspective sectional illustration through the light-emitting diode arrangement 10 according to FIG. 1.

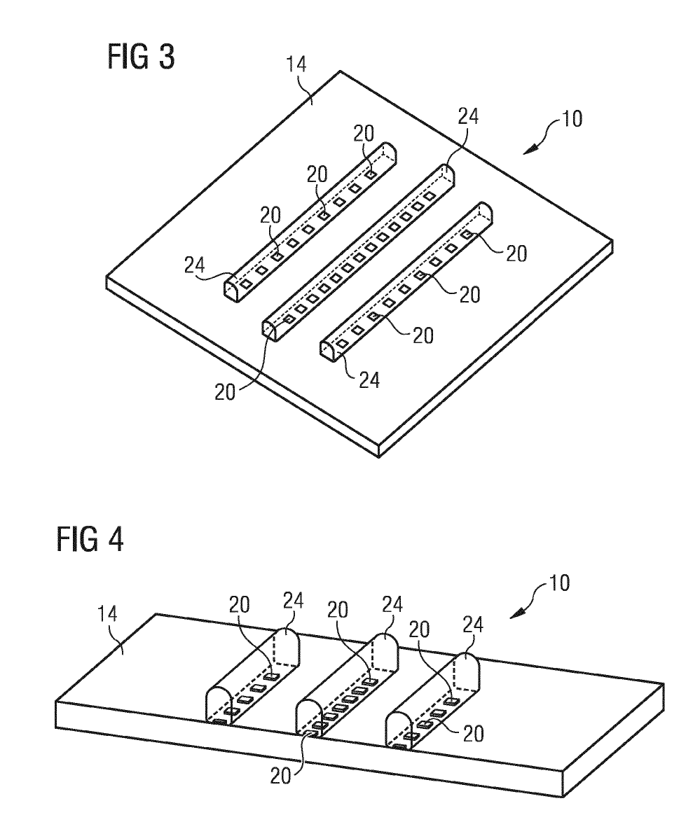

FIG. 3 shows a perspective view of a state of the light-emitting diode arrangement 10 according to FIG. 1 during its production. In particular, FIG. 3 shows the metal core board 14, on which the first LEDs 20 and the cover bodies 24 over the first LEDs 20 are already arranged. The first LEDs 20 are fastened on the metal core board 14 and are electrically connected to the electrical lines of the metal core board 14. For example, the first LEDs 20 are mechanically and/or electrically connected by means of solder connections to the metal core board 14. The first LEDs 20, which are arranged below the same cover body 24, are electrically connected in series. The first LEDs 20, which are arranged under one of the cover bodies 24, are electrically connected in parallel to the first LEDs 20, which are arranged under another of the cover bodies 24. Alternatively thereto, the first LEDs 20, which are arranged under the same cover body 24, can be electrically connected in parallel and/or the first LEDs 20, which are arranged under one of the cover bodies 24, can be electrically connected in series to the first LEDs 20, which are arranged under another of the cover bodies 24.

FIG. 4 shows a perspective sectional illustration through the light-emitting diode arrangement according to FIG. 3.

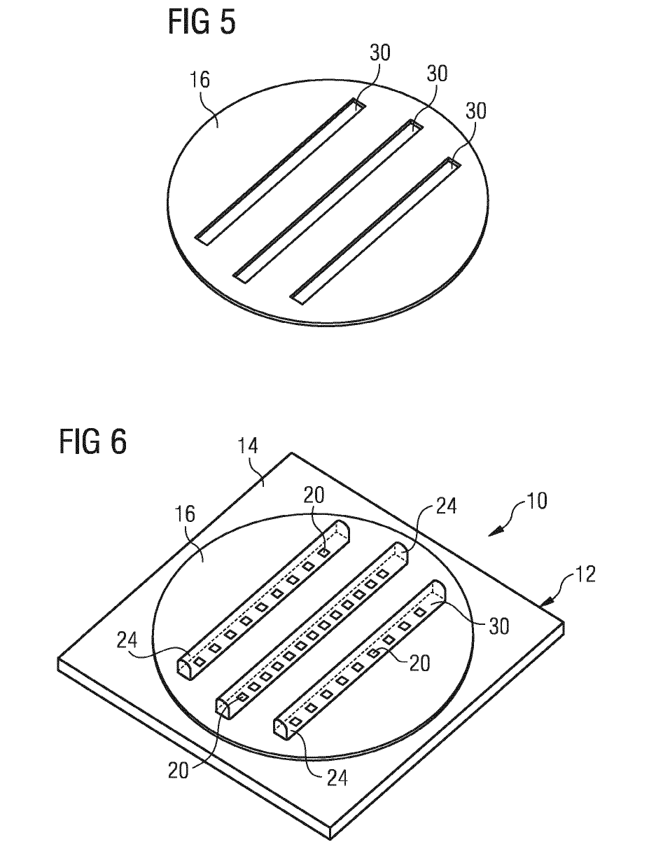

FIG. 5 shows a perspective illustration of the metal template 16. The metal template 16 has multiple, in particular three, parallel and linear recesses 30. Alternatively thereto, the metal template 16 can also, depending on the shape and number of the cover bodies 24, have more or fewer and/or differently shaped and/or differently arranged recesses.

FIG. 6 shows a perspective view of a state of the light-emitting diode arrangement 10 according to FIG. 1 during its production. In particular, FIG. 6 shows a state of the light-emitting diode arrangement 10 according to the state shown in FIGS. 3 and 4. In particular, the metal template 16 shown in FIG. 5 is arranged on the metal core board 14 such that the first LEDs 20 are arranged in the recesses 20, and the cover bodies 24 extend through the recesses 30. Measured from a surface of the metal core board 14, a height of the cover body 24 is greater than a thickness of the metal template 16.

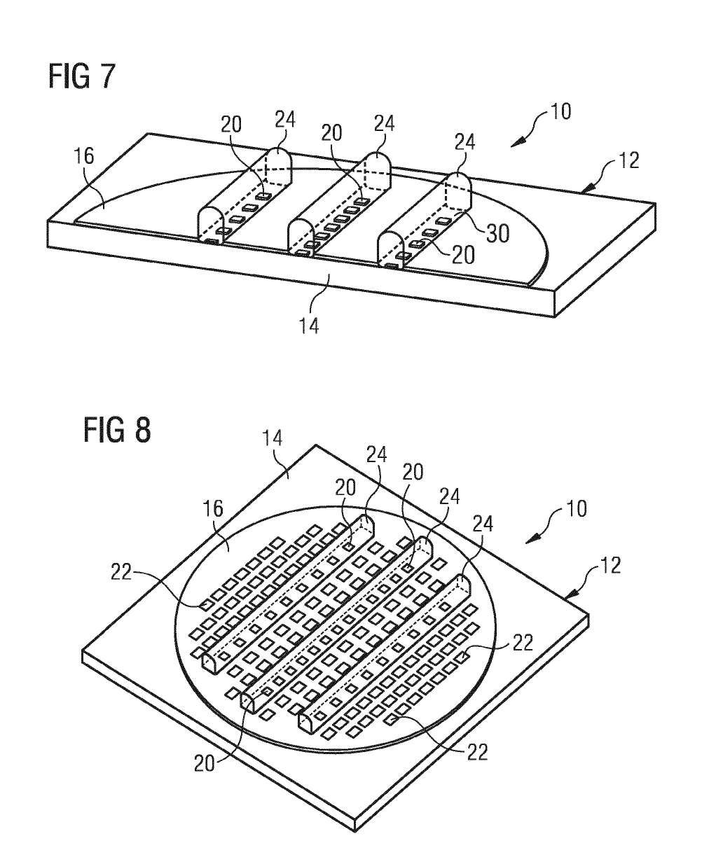

FIG. 7 shows a perspective sectional illustration through the light-emitting diode arrangement 10 according to FIG. 6.

FIG. 8 shows a perspective view of a state of the light-emitting diode arrangement 10 according to FIG. 1 during its production. In particular, FIG. 8 shows a state of the light-emitting diode arrangement 10 after the state shown in FIGS. 6 and 7. In particular, the second LEDs 22 are arranged on the metal template 16. The second LEDs 22 are mechanically fastened on the metal template 16 and are electrically connected to one another from LED 22 to LED 22, for example, by means of chip-to-chip bonding. The second LEDs 22 are mechanically connected to the metal template 16, for example, by means of adhesive material. The second LEDs 20 are arranged along lines parallel to one another. The second LEDs 22 along one of the lines are electrically connected in series. The second LEDs 22 along one of the lines are electrically connected in parallel to the second LEDs 22 along another of the lines. Alternatively thereto, the second LEDs 22 along one of the lines can be electrically connected in parallel and/or the second LEDs 22 along one of the lines can be electrically connected in series to the second LEDs 22 along another of the lines.

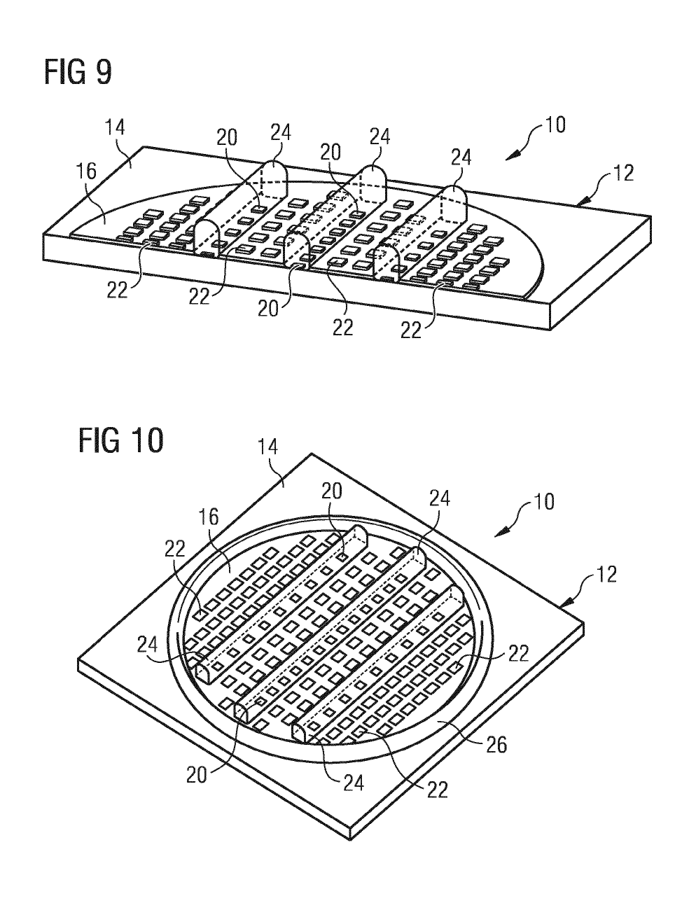

FIG. 9 shows a perspective sectional illustration through the light-emitting diode arrangement 10 according to FIG. 8.

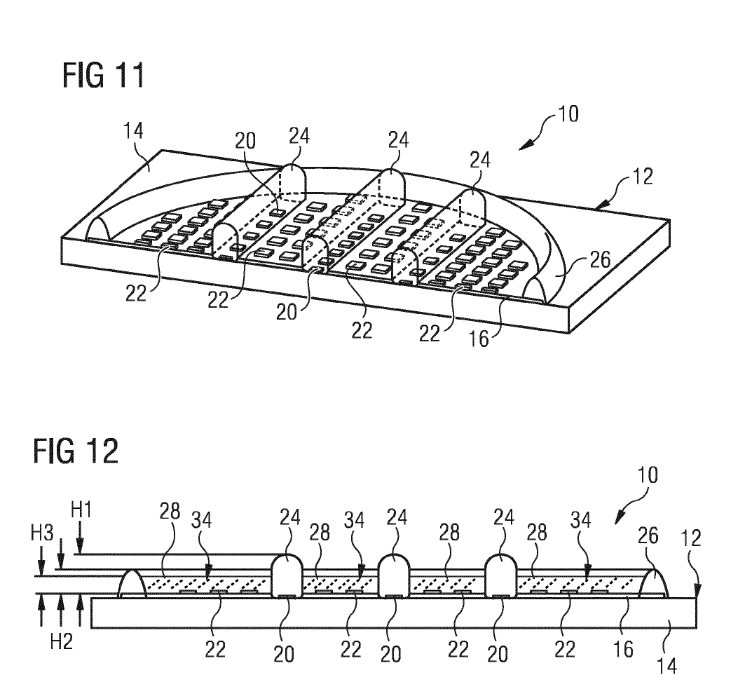

FIG. 10 shows a perspective view of a state of the light-emitting diode arrangement 10 according to FIG. 1 during its production. In particular, FIG. 10 shows a state of the light-emitting diode arrangement 10 after the state shown in FIGS. 8 and 9. In particular, the dam 26 is formed on the substrate 12. The dam 26 can be formed on the metal template 16 or on the metal core board 14. The dam 26 and the cover body 24 form the lateral delimitations of a cavity, which in FIG. 11 is delimited on the bottom by the metal template 16 and which is open on top. The cavity is suitable for decanting the first potting material 28 in the liquid state, wherein a filling height of the first potting material 28 is selected so that the first potting material 28 cannot flow over the first dam 26 and/or over the cover bodies 24.

FIG. 11 shows a perspective sectional illustration through the light-emitting diode arrangement 10 according to FIG. 11.

FIG. 12 shows a sectional illustration of a state of the light-emitting diode arrangement 10 according to FIG. 1 during its production. In particular, FIG. 12 shows a state of the light-emitting diode arrangement 10 after the state shown in FIGS. 10 and 11. In particular, the first potting material 28 is formed on the second LEDs 22, in particular directly on the second LEDs 22. After the decanting of the first potting material 28, the first potting material 28 is dried and/or cured, for example, under heat action and/or in a drying room or drying furnace. The cover bodies 24 have a first height H1. The dam 26 has a second height H2. The first potting material 28 has a third height H3. The heights H1, H2, H3 are each measured from a surface of the substrate 12, in particular from a surface of the metal template 16. The third height H3 of the potting material 28 is less than the first height H1 of the cover bodies 24 and/or the second height H2 of the dam 26.

The first potting material 28 includes a first converter material. For example, the first converter material is embedded in a carrier material of the first potting material 28. The first converter material may include converter particles 34. Alternatively, the first potting material 28 can be formed by the first converter material. The first converter material is suitable for converting electromagnetic radiation with respect to its wavelength. In particular, the first converter material converts the electromagnetic radiation generated by the second LEDs 22. For example, the second LEDs 22 emit blue light, the first converter material absorbs at least a part of the blue light and emits yellow or mint-colored light, whereby white light can be generated. Alternatively thereto, the blue light can be converted by means of first converter material into yellow light and can be converted by second converter material into bluish-white light, whereby adjustable or tunable white light can be generated.

Alternatively thereto, the cover bodies 24 may include the first converter material or a second converter material and/or the second potting material may include no converter material. The second converter material possibly differs from the first converter material. For example, the excited second converter material can emit light of a different wavelength than the first converter material and/or the second converter material can be excited by light of different wavelengths than the first converter material. Furthermore, the first converter material can be arranged laterally adjacent to one of the cover bodies 24 on a first side of the corresponding cover body 24 and the second potting material can be arranged on a second side of the corresponding cover body 24, which faces away from the first side. Thus, for example, in the exemplary embodiment shown in FIG. 12, four different potting materials can each be arranged separated from one another by the cover bodies 24.

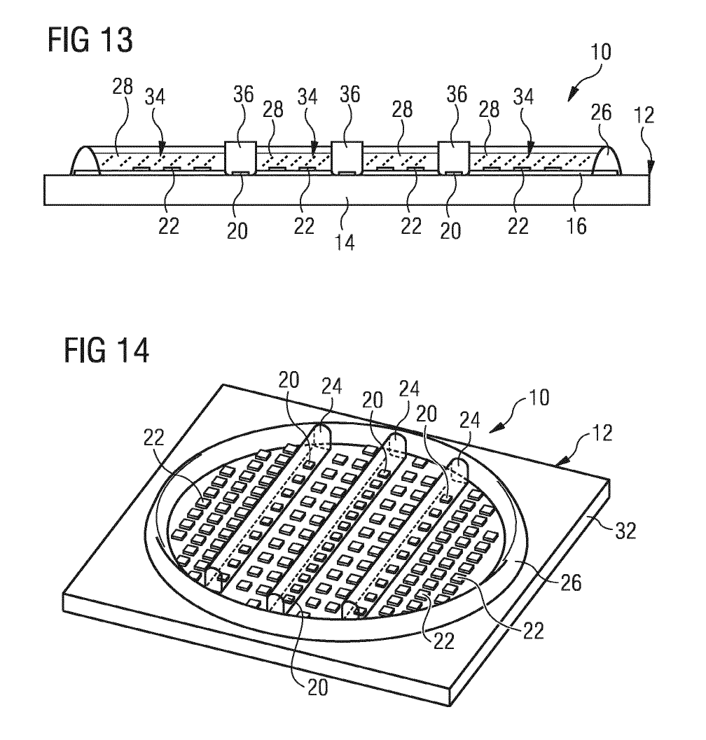

FIG. 13 shows a sectional illustration of an exemplary embodiment of a light-emitting diode arrangement 10, which can substantially correspond to one of the above-explained light-emitting diode arrangements 10. The light-emitting diode arrangement 10 is illustrated along a section line, on which no cover bodies 24 are located and which extends in parallel, for example, to one of the cover bodies 24. The light-emitting diode arrangement 10 includes at least one intermediate dam 36, for example, three intermediate dams 36. The intermediate dams are not arranged above the first LEDs 20, have no protective function, and also have no beamforming function. The intermediate dams 36 are used solely for delimiting various potting materials, wherein the various potting materials may include, for example, various converter materials accordingly. Alternatively thereto, two or more than three intermediate dams 36 can also be arranged.

FIG. 14 shows a perspective view of an exemplary embodiment of a light-emitting diode arrangement 10. The light-emitting diode arrangement 10 and the method for producing the light-emitting diode arrangement 10 can substantially correspond to the above-explained light-emitting diode arrangement 10 and/or the method for producing the light-emitting diode arrangement 10, wherein the substrate 12 includes, instead of the metal core board 14 and the metal template 16, a ceramic body 32, which has at least one highly reflective surface. The first LEDs 20 and the second LEDs 22 are arranged directly on the ceramic body 32 and/or on electrical conductor tracks (not shown), which are formed directly on the ceramic body 32, and are electrically connected to the electrical conductor tracks. The dam 26 and the cover bodies 24 in turn form the cavity for decanting the first potting material 28 in the liquid state.

While the disclosed embodiments have been particularly shown and described with reference to specific embodiments, it should be understood by those skilled in the art that various changes in form and detail may be made therein without departing from the spirit and scope of the disclosed embodiments as defined by the appended claims. The scope of the disclosed embodiments is thus indicated by the appended claims and all changes which come within the meaning and range of equivalency of the claims are therefore intended to be embraced.

1. A light-emitting diode arrangement, comprising
a substrate,
first LEDs, which are arranged on the substrate,
second LEDs, which are arranged on the substrate laterally adjacent to the first LEDs,
at least one cover body, which covers the first LEDs,
at least one dam, which is arranged on the substrate and which encloses the first LEDs and the second LEDs in the lateral direction, and
a first potting material, which covers the second LEDs and is delimited in the lateral direction by the dam and the cover body, wherein the cover body and/or the first potting material comprise(s) a first converter material for converting electromagnetic radiation.

2. The light-emitting diode arrangement as claimed in claim 1, wherein the cover body is formed as a beamforming element for influencing a beam path of electromagnetic radiation emitted by the first LEDs, in particular as an optical lens.

3. The light-emitting diode arrangement as claimed in claim 1, wherein the cover body is made transparent and the first potting material comprises the first converter material.

4. The light-emitting diode arrangement as claimed in claim 1, wherein the first LEDs emit electromagnetic radiation in the wavelength range of red visible light and wherein the second LEDs emit electromagnetic radiation in the wavelength range of blue visible light.

5. The light-emitting diode arrangement as claimed in claim 1, wherein the first LEDs are surface-emitting light-emitting diodes and wherein the second LEDs are volume-emitting light-emitting diodes.

6. The light-emitting diode arrangement as claimed in claim 1, wherein the substrate comprises
a ceramic body, which has a highly reflective surface, on which the first LEDs and the second LEDs are arranged, and
electrical lines, which are formed on the ceramic body and which are electrically coupled to the first LEDs and the second LEDs.

7. The light-emitting diode arrangement as claimed in claim 1, wherein the substrate comprises
a metal core board, on which the first LEDs are arranged, and
a metal template, which is arranged on the metal core board, the surface of which facing away from the metal core board is highly reflective, and on which the second LEDs are arranged and which comprises recesses, in which the first LEDs are arranged and through which the cover bodies protrude.

8. The light-emitting diode arrangement as claimed in claim 1, further comprising third LEDs, which are arranged on the substrate laterally adjacent to the first LEDs and the second LEDs.

9. The light-emitting diode arrangement as claimed in claim 8, wherein the third LEDs are designed as structurally equivalent to the first LEDs or the second LEDs.

10. The light-emitting diode arrangement as claimed in claim 8, further comprising a second potting material, wherein the second potting material comprises a second converter material for converting electromagnetic radiation, covers the third LEDs.

11. The light-emitting diode arrangement as claimed in claim 8, further comprising at least one intermediate dam, which is arranged on the substrate laterally between the first LEDs, the second LEDs, and/or the third LEDs and which delimits the first potting material and/or the second potting material in the lateral direction.

12. A method for producing a light-emitting diode arrangement
providing a substrate,
arranging first LEDs on the substrate,
arranging second LEDs on the substrate laterally adjacent to the first LEDs,
forming and arranging at least one cover body over the first LEDs so that it covers the first LEDs,
arranging at least one dam on the substrate so that it encloses the first LEDs and the second LEDs in the lateral direction, and
pouring a liquid first potting material between the cover body and the dam over the second LEDs so that it is delimited in the lateral direction by the dam and the cover body, wherein the cover body and/or the first potting material comprises a first converter material for converting electromagnetic radiation, and
wherein the first potting material is dried and/or cured.

13. The method as claimed in claim 12, wherein the cover body is designed as a beamforming element for influencing a beam path of electromagnetic radiation emitted by the first LEDs, in particular as an optical lens.

14. The method as claimed in claim 12, wherein
the first LEDs are arranged on a metal core board,
the cover body is arranged over the first LEDs,
a metal template, the surface of which facing away from the metal core board is highly reflective and which comprises recesses, is formed and arranged on the metal core board so that the first LEDs are arranged in the recesses and the cover body protrudes through the recesses, and
the second LEDs are arranged on the highly reflective surface of the metal template, wherein the metal core board and the metal template form the substrate.

15. The method as claimed in claim 12, further comprising
arranging third LEDs on the substrate laterally adjacent to the first LEDs and the second LEDs,
a liquid second potting material, which comprises a second converter material for converting electromagnetic radiation, is poured over the third LEDs such that it covers the third LEDs, and
the second potting material is dried and/or cured.

16. The method as claimed in claim 15, further comprising forming an intermediate dam on the substrate laterally between the first LEDs, the second LEDs, and/or the third LEDs so that it delimits the first potting material and/or the second potting material in the lateral direction.
